(19) United States
(12) Patent Application Publication
(10) Pub. No.: US 2010/0002392 A1
(43) Pub. Date: Jan. 7, 2010

(54) Assembled Heat Sink Structure

(76) Inventor: I-Ming LIU, Tainan County (TW)

Correspondence Address: FRENKEL & ASSOCIATES, 3975 UNIVERSITY DR., STE. 330, FAIRFAX, VA, 22030, US

(21) Appl. No.: 12/168,188

(22) Filed: Jul. 7, 2008

(51) Int. Cl. H05K 7/20

(52) U.S. Cl. 361/699; 361/702; 361/703

(57) ABSTRACT

The present invention provides an assembled heat sink structure including a base, a plurality of heat dissipating fins mounted on the top of the base, and a capillary device located inside the base, wherein the base is formed and assembled by an upper cover with a lower cover and the mountain-shaped fin-like device for diversion or capillary is located inside the base, so that after a plurality of heat dissipating fins are assembled on the top of the base, they can be welded to form an integration. Then, a heat dissipating medium can be poured into the airtight chamber of the base, and thus, when the base is contacted with the contact surface, the heat can be absorbed by an absorbing end of the base, transmitted to a plurality of heat dissipating fins on the top of the base and then exhausted by a fan, thereby achieving heat dissipating effect.

### FIELD OF THE INVENTION

The present invention is related to an assembled heat sink structure, and more particularly to an assembled heat sink structure with great heat dissipating property.

### BACKGROUND OF THE INVENTION

Generally, for personal computers, notebooks or peripherals, the heat generating structures thereof always have heat sink structures fixed on the contacting surface thereof, and through the copper powders inside the chamber of the base of the heat sink structure, the generated heat can be dissipated. However, when dissipating heat, the base is directly contacted with the heat generating structure of the computer, so that the heat might still accumulate at the contacting surface. Besides, since it is not easy for the copper powders inside the chamber of the base to dissipate the heat, the heat from the heat generating structures is also difficult to dissipate, thereby causing the heat to remain therein. Therefore, the heat dissipating effect of the conventional heat sink structure is limited.

### SUMMARY OF THE INVENTION

The object of the present invention is to solve the problems described above by providing an assembled heat sink structure, which has a base formed and assembled by an upper cover and a lower cover through punching and a mountain-shaped fin-like diversion or capillary device located in the base, so that after a plurality of heat dissipating fins are assembled on the top of the base, a welded integration for providing heat dissipating effect can be rapidly formed.

According to one aspect of the present invention, the assembled heat sink structure is provided. The structure includes the base made of heat dissipating aluminum, a plurality of heat dissipating fins mounted on the top of the base, and the capillary device located inside the base, wherein the base is formed and assembled by the upper cover having a chamber with the lower cover through punching and the mountain-shaped fin-like device for diversion or capillary is located inside the chamber, so that after the lower cover is assembled with the upper cover and a plurality of heat dissipating fins are assembled on the top of the base, they can be welded to form an integration. Then, when the base is extracted to become vacuum and airtight, a heat dissipating medium can be poured into the airtight chamber, and thus, when the base is contacted with the contact surface of the heat generating structure in the personal computer, the notebook or the peripheral, the heat can be absorbed by an absorbing end of the base, transmitted to a plurality of heat dissipating fins on the top of the base and then exhausted by fan, thereby achieving heat dissipating effect.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 shows a three-dimensional decomposition drawing of the present invention;

FIG. 2A shows a three-dimensional assembly of the present invention;

FIG. 2B shows a sectional view of 2B-2B in FIG. 2A;

FIG. 2C shows a sectional view of 2C-2C in FIG. 2A;

FIG. 3 is a schematic view showing the extraction of a chamber in a base of the present invention;

FIG. 4 is a schematic view showing the pouring of heat dissipating medium into the chamber in the base of the present invention;

FIG. 5 is a three-dimensional decomposition drawing showing a capillary device in another embodiment of the present invention;

FIG. 6 is a three-dimensional decomposition drawing showing the capillary device in still another embodiment of the present invention;

FIG. 7 is a three-dimensional decomposition showing the integration of the base and heat dissipating fins according to the present invention;

FIG. 8 is a three-dimensional decomposition showing the base with outlet and inlet terminals at two sides thereof according to the present invention; and

FIG. 9 is a schematic view showing the arrangement between the base and a contact surface of a heat generating structure according to the present invention.

### DESCRIPTION OF THE PREFERRED EMBODIMENT

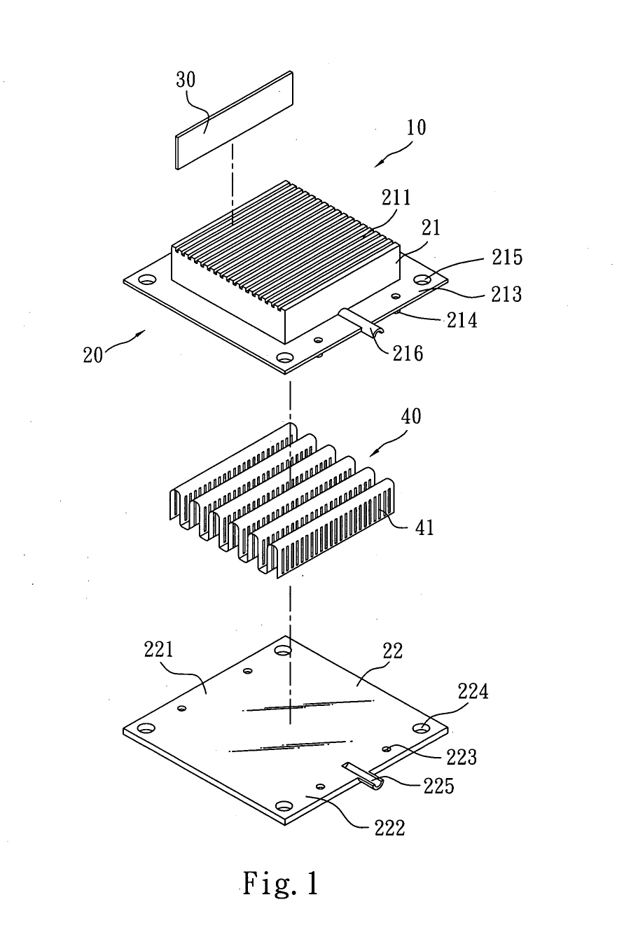

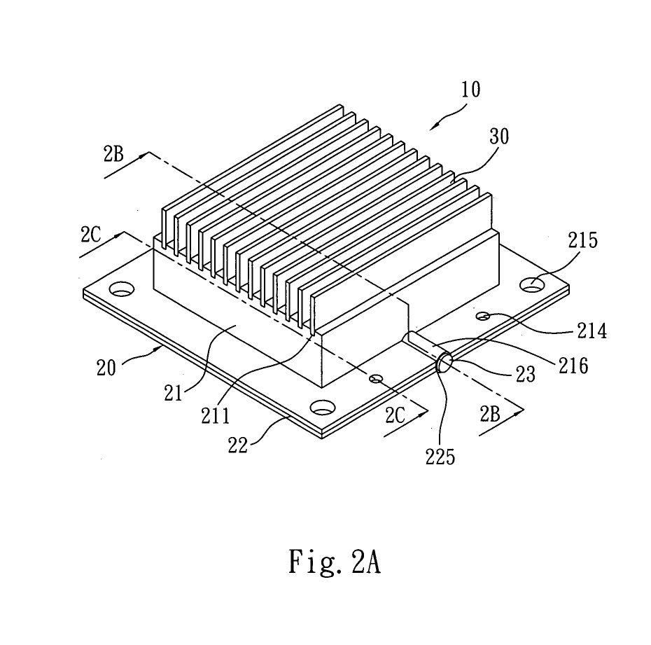

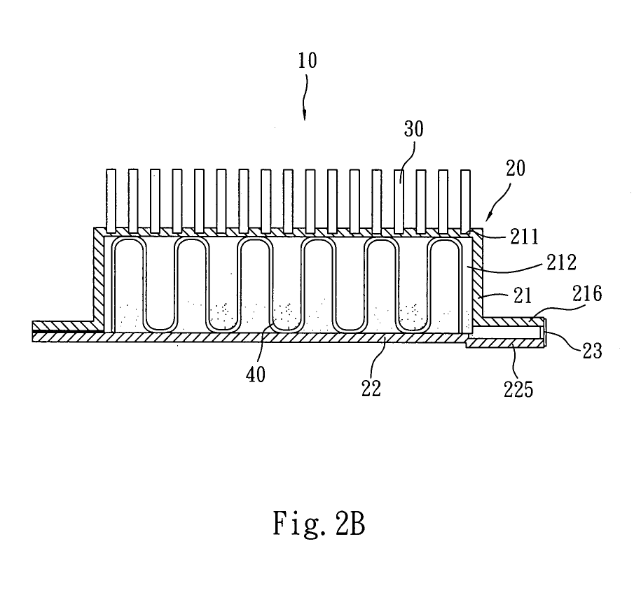

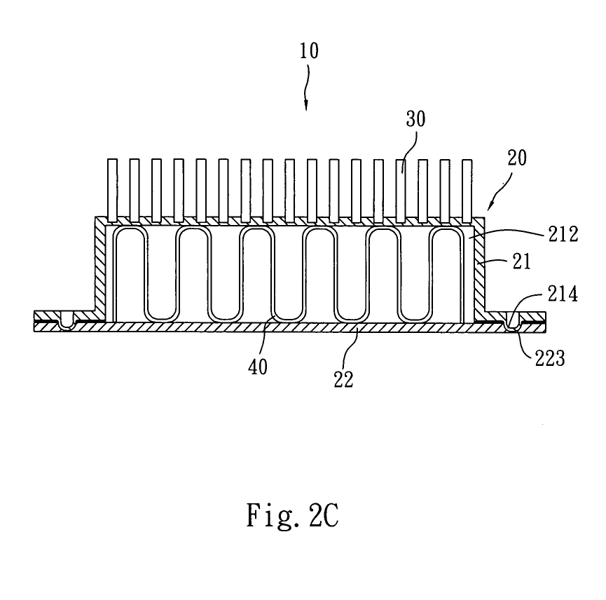

Please refer to FIG. 1, FIG. 2A, FIG. 2B and FIG. 2C. An assembled heat sink 10 includes a base 20, a plurality of heat dissipating fins 30 and a capillary device 40, wherein:

The base 20 is configured to have an upper cover 21 and a lower cover 22 which are formed and assembled by punching. The upper cover 21 has a plurality of trenches 211 mounted on the top thereof and is formed to have an inward chamber 212, and a flank 213 is extended from the surrounding edge of the upper cover 21 with a plurality of protrusions 214 mounted on two sides of the flank 213, first engaging holes 215 for engaging processors (not shown in the drawing) at each corner of the flank 213 and a hollow first arc tube 216 mounted at the center position of one side of the flank 213. The lower cover 22 is a flat plate having a plurality of indentations 223 located at two sides 221, 222 thereof for correspondingly engaging with a plurality of protrusions 214 on the upper cover 21, second engaging holes 224 corresponding to the first engaging holes 215 located at each corner thereof, wherein the first and the second engaging holes 215, 224 are fixed by penetrating an engaging element (not shown in the drawing), and a second arc tube 225 located at the center position of one side 222 thereof for correspondingly assembling with the first arc tube 216, so as to be covered by a seal 23.

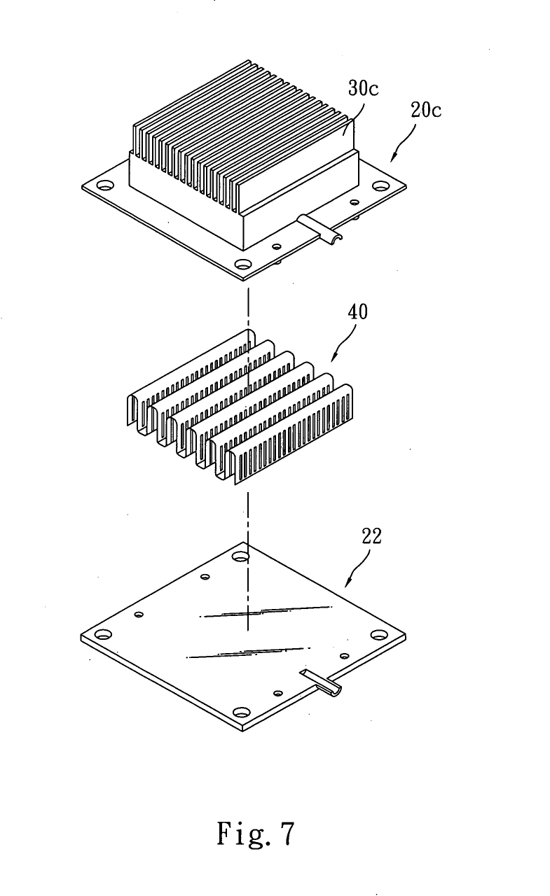

A plurality of heat dissipating fins 30 are flat pieces respectively connected to a plurality of trenches 211 on the top of the upper cover 21 of the base 20, or as shown in FIG. 7, a plurality of heat dissipating fins 30c are integrally formed with the base 20c.

The capillary device 40 is mounted in the chamber 212 of the base 20. Then, the base 20, a plurality of heat dissipating fins 30 and the capillary device 40 are welded to form integration.

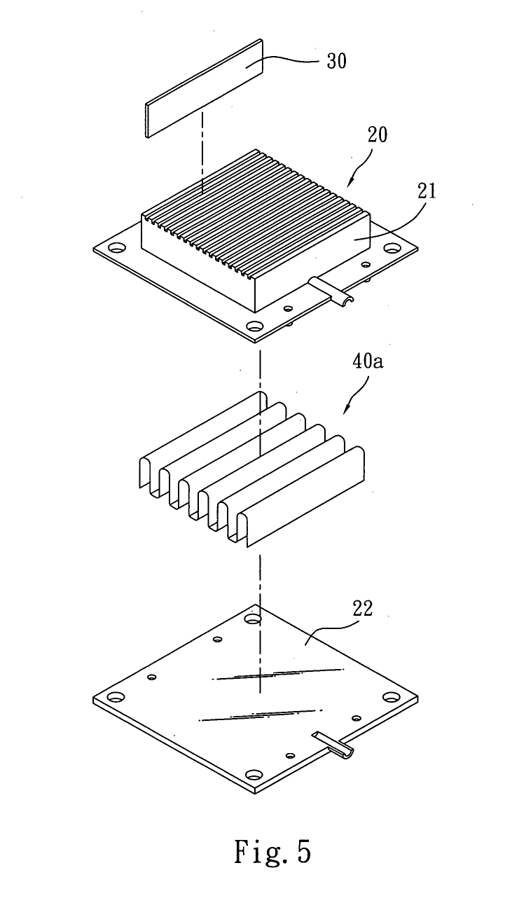

Moreover, the capillary device 40 mounted inside the base 20 can be a mountain-shaped fin-like device with windows 41 or without windows (as the capillary device 40a shown in FIG. 5).

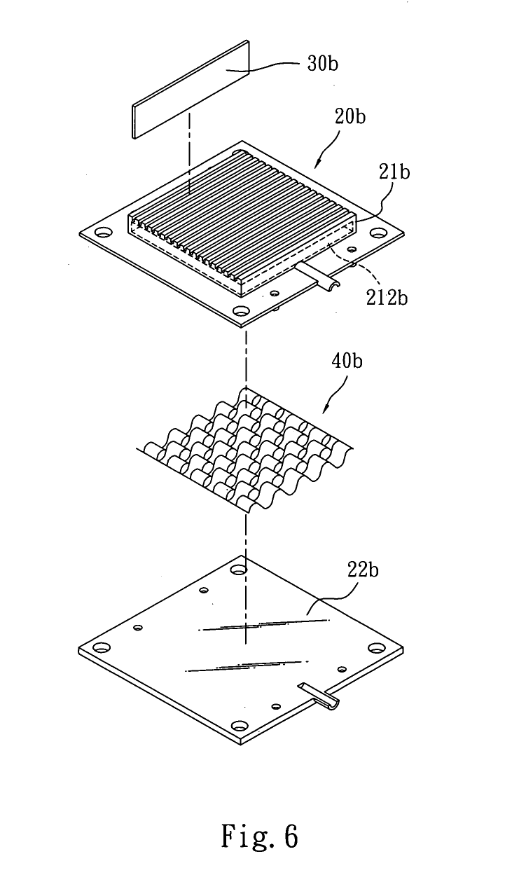

Please further refer to FIG. 6. The base 20b is formed and assembled by the upper cover 21b having the chamber 212b with the lower cover 22b through punching, and a heat dissipating device 40b for diversion or capillarity is located inside the chamber 212b, which is inwardly formed by the upper cover 21b, so that after the lower cover 22b is assembled with the upper cover 21b and a plurality of heat dissipating fins 30b are assembled on the top of the base 20b, they can be welded to form an integration.

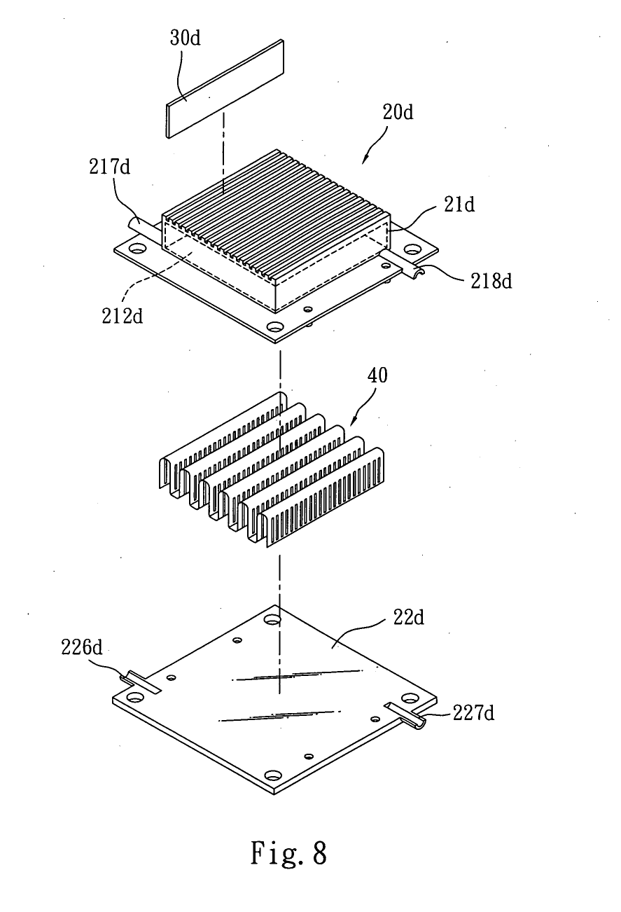

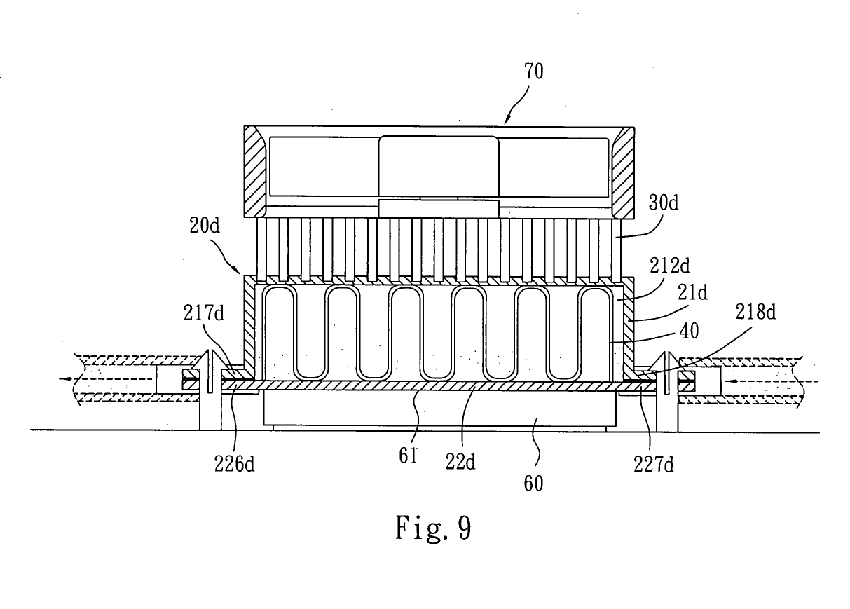

Furthermore, please refer to FIG. 8 and FIG. 9. The base 20d is formed and assembled by the upper cover 21d with the lower cover 22d through punching, wherein the upper cover 21d is formed to have the inward chamber 212d for positioning the capillary device 40. The assembled base 20d has outlet terminals 217d, 226d at one side thereof and inlet terminals 218d, 227d at the other side thereof so as to participate in an external heat exchange system (as indicated by the arrows in FIG. 9). Therefore, when the base 20d is contacted with a contact surface 61 of a heat generating structure 60 in the personal computer, the notebook or the peripheral, the heat can be absorbed by a heat absorbing end of the base 20d, transmitted to a plurality of heat dissipating fins 30d on the top of the base 20d and then exhausted by a fan 70, thereby achieving the effect of heat dissipating.

According to the present invention, when assembling, as shown in FIG. 2B and FIG. 2C, the base 20 is formed and assembled by the upper cover 21 having the chamber 212 with the lower cover 22 through punching, wherein the mountain-shaped fin-like device 40 for diversion or capillary is located inside the chamber 212, and followed by the lower cover 22 assembling with the upper cover 21 and a plurality of heat dissipating fins 30 assembling on the top of the base 20, so that they can be welded to form an integration.

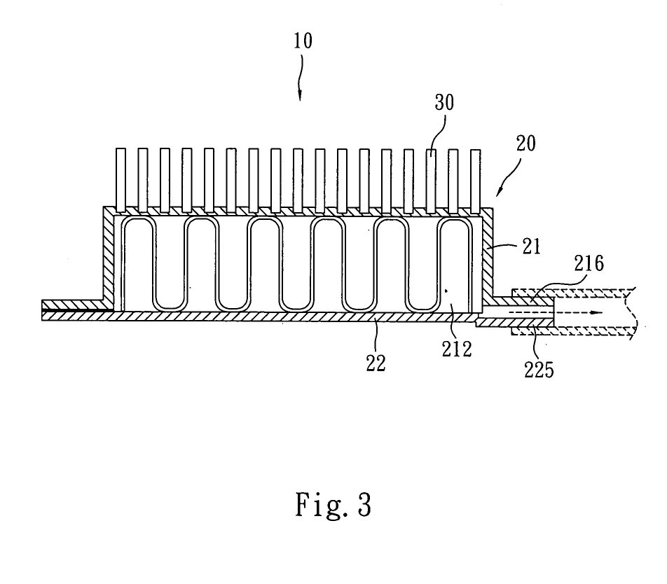

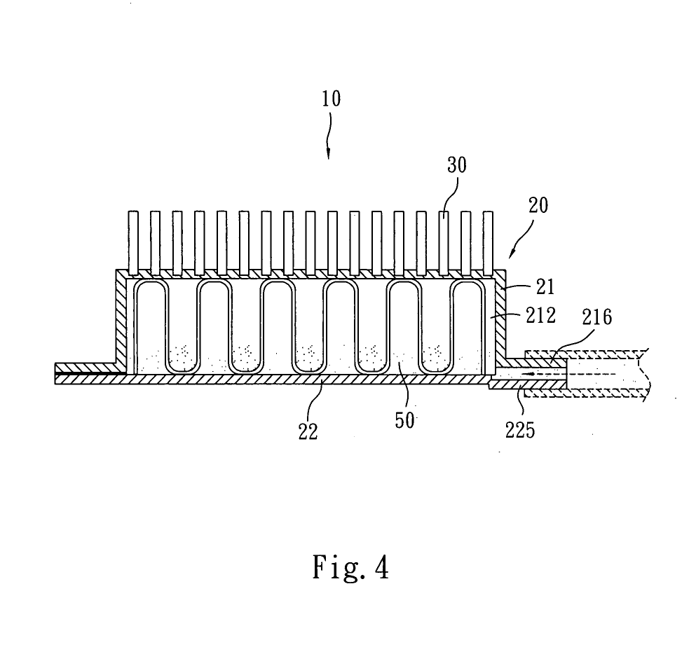

Furthermore, improving the conventional heat sink, as shown in FIG. 3, after the upper and the lower covers 21, 22 are assembled to form the base 20, the first and the second arc tubes 216, 225 can be used to extract air in the chamber (as indicated by the arrow in FIG. 3), so that the chamber 212 becomes vacuum and airtight. Then, a liquid heat dissipating medium 50, such as, water or refrigerant, can be poured into the airtight chamber 212 (as indicated by the arrow in FIG. 4) in an amount of 3˜30 v % in accordance with the capacity of the chamber and the heat dissipating demands. Therefore, when the base 20 is contacted with the contact surface of the heat generating structure in the personal computer, the notebook or the peripheral, the heat can be absorbed by the absorbing end of the base 20, transmitted to a plurality of heat dissipating fins 30 on the top of the base 20 and then exhausted by the fan 70, thereby achieving the heat sink 10 with great heat dissipating property.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An assembled heat sink structure, comprising:
a base, configured to have an upper cover and a lower cover so as to form a chamber therebetween;
a plurality of heat dissipating fins, connected to the top of the upper cover of the base; and
a capillary device, mounted in the chamber between the upper and the lower cover, wherein the base, a plurality of hest dissipating fins and the capillary device are welded to form an integration.

2. The assembled heat sink structure as claimed in claim 1, wherein the chamber is extracted to become vacuum and airtight, and a heat dissipating medium is poured into the airtight chamber for transmitting the heat from the heat absorbing end of the base to a plurality of heat dissipating fins at the top, so that the heat is exhausted by a fan, thereby achieving a heat dissipating effect.

3. The assembled heat sink structure as claimed in claim 2, wherein the heat dissipating medium is a liquid, such as water or refrigerant, and the poured amount of the heat dissipating medium is ranged from 3 v % to 30 v % in accordance with the capacity of the chamber and the heat dissipating demands.

4. The assembled heat sink structure as claimed in claim 1, wherein the base is formed and assembled by the upper and the lower covers through punching and is assembled with the mountain-shaped fin-like capillary device to form integration through welding.

5. The assembled heat sink structure as claimed in claim 1, wherein the base and a plurality of heat dissipating fins of the heat sink structure are made of aluminum.

6. The assembled heat sink structure as claimed in claim 1, wherein the capillary device in the base is the mountain-shaped fin-like capillary device with windows.

7. The assembled heat sink structure as claimed in claim 1, wherein the capillary device in the base is the mountain-shaped fin-like capillary device without windows.

8. The assembled heat sink structure as claimed in claim 1, wherein the base is formed and assembled by the upper cover having the chamber with the lower cover through punching, and a heat dissipating device for diversion or capillarity is located inside the chamber, so that after the lower cover is assembled with the upper cover and then a plurality of heat dissipating fins are assembled on the top of the base, they are welded to form an integration.

9. The assembled heat sink structure as claimed in claim 1, wherein the base and a plurality of hest dissipating fins are integrally formed.

10. The assembled heat sink structure as claimed in claim 1, wherein the base has outlet terminals at one side thereof and inlet terminals at the other side thereof so as to participate in an external heat exchange system.
